(19) United States
(12) Patent Application Publication
(10) Pub. No.: US 2006/0049715 A1
(43) Pub. Date: Mar. 9, 2006

(54) Method and appartus for driving electro-mechanical transducer

(75) Inventor: Hitoshi Onishi, Niigata-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/210,517

(22) Filed: Aug. 22, 2005

(30) Foreign Application Priority Data
Aug. 27, 2004 (JP) 2004-247650

(51) Int. Cl. H01L 41/09

(52) U.S. Cl. 310/317

(57) ABSTRACT

Two piezoelectric ceramics are equal to each other in the polarization directions thereof. Two electrodes disposed on both surfaces of one of the piezoelectric ceramics are connected to an AC voltage source, while other two electrodes disposed on both surfaces of the other piezoelectric ceramic are connected to another AC voltage source having a phase 180° (2π) different from that of the AC voltage source. The two AC voltage sources are biased to a positive voltage side. Accordingly, the invention provides an electro-mechanical transducer capable of greatly increasing the displacement amount of the film thickness of the electromechanical transducer and of preventing the polarization loss of the electro-mechanical transducer.

### BACKGROUND OF THE INVENTION

1. Field of the Invention

The present invention relates to a method and apparatus for driving an electromechanical transducer whose film thickness is changed by applying a voltage, and more particularly, to a method and apparatus for driving an electro-mechanical transducer, which is capable of greatly increasing the displacement amount of the film thickness thereof.

2. Description of the Related Art

FIG. 9 is a cross-sectional view of a conventional piezoelectric element (electro-mechanical transducer) D.

Each electrode 2 is disposed on upper and lower surfaces of a piezoelectric ceramic 1, respectively. The piezoelectric ceramic 1 is subjected to a polarization process in the thickness direction thereof. The electrodes 2 are connected to an alternating current (AC) voltage source A. An AC driving voltage supplied from the AC voltage source A has a sine wave shape, as shown in FIG. 13, in which an absolute value of a maximum voltage at a positive side is the same as that of a minimum voltage at a negative side.

When an applied voltage direction and a polarization direction of the piezoelectric ceramic 1 are equal to each other, the piezoelectric element D expands the film thickness in the voltage direction. Meanwhile, when the voltage direction is opposite to the polarization direction of the piezoelectric ceramic 1, the piezoelectric element D contracts in the voltage direction.

FIG. 10 is a cross-sectional view of a stacked piezoelectric element D1 in which a plurality of piezoelectric elements, such as the piezoelectric element D shown in FIG. 9, are stacked. Reference numerals 1a, 1b, 1c, 1d, and 1e denote piezoelectric ceramics, and reference numerals 2a, 2b, 2c, 2d, 2e, and 2f denote electrodes. The polarization directions of the piezoelectric ceramics 1a, 1c, and 1e are opposite to the polarization directions of the piezoelectric ceramics 1b and 1d. That is, the polarization directions of adjacent piezoelectric ceramics are opposite to each other. The electrodes 2b, 2d, and 2f are connected to a terminal 3 of the AC voltage source A, and the electrodes 2a, 2c, and 2e are connected to terminal 4.

An AC driving voltage supplied from the AC voltage source A connected to the stacked piezoelectric element D1 also has a waveform shown in FIG. 13. When the terminal 3 has a positive voltage with respect to the terminal 4, a maximum forward voltage in the polarization direction is applied to the piezoelectric ceramics 1a, 1b, 1c, 1d, and 1e, and the piezoelectric ceramics 1a, 1b, 1c, 1d, and 1e expand the film thicknesses in the applied voltage direction. Meanwhile, when the terminal 3 has a negative voltage with respect to the terminal 4, a maximum reverse voltage in a direction opposite to the polarization direction is applied to the piezoelectric ceramics 1a, 1b, 1c, 1d, and 1e, and the piezoelectric ceramics 1a, 1b, 1c, 1d, and 1e contracts the film thickness in the applied voltage direction.

FIG. 11 is a cross-sectional view of a piezoelectric element D3 in which two piezoelectric elements, such as the piezoelectric element D shown in FIG. 9, are stacked. Reference numerals 1f and 1g denote piezoelectric ceramics, and reference numerals 2g, 2h, and 2i denote electrodes. The piezoelectric ceramics 1f and 1g are equal to each other in the polarization direction. The electrodes 2g and 2i are connected to a terminal 3 of the AC voltage source A, and the electrode 2h is connected to a terminal 4. Such a stacked piezoelectric element D3 is called a parallel piezoelectric bimorph element. Also, a metallic plate may be provided in a central portion of the electrode 2h.

An AC driving voltage supplied from the AC voltage source A connected to the stacked piezoelectric element D3 also has a waveform shown in FIG. 13. When the terminal 3 has a positive voltage with respect to the terminal 4, a maximum forward voltage in a polarization direction is applied to the piezoelectric ceramic 1g so that the piezoelectric ceramic 1g expands the film thickness in the applied voltage direction and contracts the film thickness in the direction orthogonal to the voltage direction. Also, a maximum reverse voltage in the direction opposite to the polarization direction is applied to the piezoelectric ceramic 1f so that the piezoelectric ceramic 1f contracts the film thickness in the applied voltage direction and expands the film thickness in the direction orthogonal to the voltage direction. Meanwhile, when the terminal 3 has a negative voltage with respect to the terminal 4, a maximum reverse voltage is applied to the piezoelectric ceramic 1g so that the piezoelectric ceramic 1g contracts the film thickness in the applied voltage direction and expands the film thickness in the direction orthogonal to the voltage direction. Also, a maximum forward voltage is applied to the piezoelectric ceramic 1f so that the piezoelectric ceramic 1f expands the film thickness in the applied voltage direction and contracts the film thickness in the direction orthogonal to the voltage direction. Such an expansion and contraction of the piezoelectric ceramics 1g and 1f causes the stacked piezoelectric element D3 to make a curvature movement.

FIG. 12 is a cross-sectional view of a stacked piezoelectric element D4 in which two piezoelectric elements, such as the piezoelectric element D shown in FIG. 9, are stacked. Reference numerals 1h and 1i denote piezoelectric ceramics, and reference numerals 2j, 2k, and 2l denote electrodes. The piezoelectric ceramic 1h is opposite in polarization direction to the piezoelectric ceramic 1i. The electrode 2l is connected to a terminal 3 of the AC voltage source A, and the electrode 2j is connected to a terminal 4. Such a stacked piezoelectric element D4 is called a serial piezoelectric bimorph element. Also, a metallic plate may be provided in a central portion of the electrode 2k.

An AC driving voltage supplied from the AC voltage source A connected to the stacked piezoelectric element D4 also has a waveform shown in FIG. 13. When the terminal 3 has a positive voltage with respect to the terminal 4, a maximum forward voltage in a polarization direction is applied to the piezoelectric ceramic 1i so that the piezoelectric ceramic 1i expands the film thickness in the applied voltage direction and contracts the film thickness in the direction orthogonal to the voltage direction. Also, a maximum reverse voltage in the direction opposite to the polarization direction is applied to the piezoelectric ceramic 1h so that the piezoelectric ceramic 1h contracts the film thickness in the applied voltage direction and expands the film thickness in the direction orthogonal to the voltage direction. Meanwhile, when the terminal 3 has a negative voltage relative to the terminal 4, a maximum reverse voltage is applied to the piezoelectric ceramic 1i so that the piezoelectric ceramic 1i contracts in the film thickness in the applied voltage direction of and expands the film thickness in the direction orthogonal to the voltage direction. Also, a maximum forward voltage is applied to the piezoelectric ceramic 1h so that the piezoelectric ceramic 1h expands the film thickness in the applied voltage direction and contracts the film thickness in the direction orthogonal to the voltage direction. Such an expansion and contraction of the piezoelectric ceramics 1i and 1h causes the stacked piezoelectric element D4 to make a curvature movement.

The above-mentioned piezoelectric elements are disclosed in U.S. Pat. No. 5,233,256 and Japanese Unexamined Patent Application Publication No. 6-232469.

The polarization disappears in the polarized piezoelectric ceramic when an electric field, having a value not less than a predetermined value (product of a voltage and a film thickness), is applied to the piezoelectric ceramic in a direction opposite to the polarization direction. A maximum reverse electric field by which the polarization disappears is called a coercive field strength. Accordingly, it is necessary to make a maximum reverse voltage in the direction opposite to the polarization direction smaller than the predetermined value based on the coercive field strength.

According to the conventional method and apparatus for driving the electromechanical transducer which uses an AC voltage source A, an AC driving voltage is applied such that the absolute value of a maximum voltage at a positive side is the same as that of a maximum voltage at a negative side. Thus, there is a restriction in that a maximum forward voltage applied to a piezoelectric ceramic is at most equal to a maximum reverse voltage determined by the coercive field strength. Further, the maximum forward voltage is usually smaller by 20% or more than the maximum reverse voltage. To overcome such a restriction, U.S. Pat. No. 5,233,256 discloses that, when a voltage is applied to a piezoelectric element in which a plurality of piezoelectric ceramics having different polarization directions are connected in series to each other, a high voltage can be applied by the piezoelectric element since a maximum forward voltage becomes larger than a maximum reverse voltage due to the hysteresis of the piezoelectric ceramic.

In addition, Japanese Unexamined Patent Application Publication No. 6-232469 discloses that a bias voltage is superposed on a driving voltage to prevent polarization loss.

However, there is a problem in U.S. Pat. No. 5,233,256 in that since the piezoelectric element uses the hysteresis of the piezoelectric ceramic, a maximum voltage which can be applied to the piezoelectric element is dependent on materials forming the piezoelectric ceramic. Meanwhile, there is a problem in Japanese Unexamined Patent Application Publication No. 6-232469 in that since the piezoelectric element has a single driving voltage source, an optimum driving voltage cannot be supplied to drive a stacked piezoelectric element or a piezoelectric bimorph element.

### SUMMARY OF THE INVENTION

The invention is designed to solve the above problem, and it is an object of the invention to provide a method and apparatus for driving an electro-mechanical transducer, which is capable of greatly increasing the displacement amount of the film thickness of the electro-mechanical transducer by supplying an AC driving voltage to the electro-mechanical transducer such as a piezoelectric element.

In order to achieve the above object, according to an aspect of the invention, there is provided a method of driving an electromechanical transducer, the electro-mechanical transducer being subjected to a polarization process in one direction, being provided with electrodes on both surfaces thereof intersecting the polarization direction, and changing the film thickness thereof by applying a voltage across both electrodes. An absolute value of a maximum forward voltage applied to the electromechanical transducer in the polarization direction is set to be larger than an absolute value of a maximum reverse voltage applied in a direction opposite to the polarization direction.

Preferably, the electro-mechanical transducer is a piezoelectric element.

According to the invention, it is possible to increase the displacement amount of the film thickness of an electro-mechanical transducer while preventing polarization loss of the electromechanical transducer. In addition, since a pseudo polarization process of the electro-mechanical transducer can be performed by the maximum forward voltage having a large absolute value while it is driven, it is possible to increase a usage temperature of the electromechanical transducer.

Furthermore, according to the invention, the AC driving voltage is positive at the positive side of the voltage waveform and is negative at the negative side of the voltage waveform. A voltage rising in the polarization direction of a piezoelectric ceramic is set to be a forward voltage, and a voltage rising in the direction opposite to the polarization direction is set to be a reverse voltage.

Further, in the invention, preferably, a plurality of electromechanical transducers are stacked such that their polarization directions are equal to each other.

In this case, a bimorph electro-mechanical transducer can be driven by applying AC driving voltages having different phases to the electro-mechanical transducers. According to the invention, since the AC driving voltages having different phases are supplied to the electro-mechanical transducers, a maximum forward voltage having an optimal amplitude and a maximum reverse voltage having an optimal amplitude can be applied to each electro-mechanical transducer.

Alternatively, in the invention, preferably, a plurality of electro-mechanical transducers are stacked such that the polarization directions of adjacent electromechanical transducers are opposite to each other.

In this case, by applying AC driving voltages having opposite polarities to the electro-mechanical transducers, the absolute value of the maximum forward voltage applied in the polarization direction of the electro-mechanical transducer can be made to be larger than the absolute value of the maximum reverse voltage applied in the direction opposite to the polarization direction.

Further, a bimorph electro-mechanical transducer can be driven by applying AC driving voltages having different phases to the respective electromechanical transducers.

Alternatively, by applying AC driving voltages having the same phases to the respective electro-mechanical transducers, it is possible to drive a stacked electro-mechanical transducer in which the electromechanical transducers expand simultaneously and contract simultaneously.

In addition, when driving the stacked electro-mechanical transducer, it is possible to increase the stacked number of electromechanical transducers by adding other electromechanical transducers to the stacked electro-mechanical transducer composed of two electro-mechanical transducers. At this time, it is preferable that an AC driving voltage be applied to each of the other electromechanical transducers, the AC driving voltage being set such that the absolute value of the maximum forward voltage applied in the polarization direction is larger than the absolute value of the maximum reverse voltage applied in the direction opposite to the polarization direction.

Preferably, each of the other electromechanical transducers is opposite in polarization direction to adjacent electromechanical transducers.

In the invention, it is preferable that the absolute value of the maximum forward voltage be larger than the product of a coercive field strength, by which the polarization disappears in an electro-mechanical transducer, and the film thickness of the electro-mechanical transducer.

Also, it is preferable that the absolute value of the maximum reverse voltage is smaller than the product of a coercive field strength, by which the polarization disappears in an electro-mechanical transducer, and the film thickness of the electromechanical transducer.

As described above, according to the invention, it is possible to increase a usage temperature of the electro-mechanical transducer. When the electro-mechanical transducer is a piezoelectric element, the piezoelectric element can be used at temperatures close to the Curie temperature of the piezoelectric element. Accordingly, the invention can use a piezoelectric element having a low Curie temperature, such as barium titanate or any material which contains barium titanate as a main component but does not contain lead (Pb). Materials that do not contain lead causes a little damage to the environment.

In addition, according to another aspect of the invention, an apparatus for driving the electro-mechanical transducer includes an electro-mechanical transducer that is subjected to a polarization process in one direction, is provided with electrodes disposed on both surfaces thereof intersecting the polarization direction, and changes the film thickness by applying a voltage across both electrodes; and an AC voltage source that applies an AC driving voltage to the electro-mechanical transducer. An absolute value of a maximum forward voltage of the AC driving voltage applied to the electro-mechanical transducer in the polarization direction is larger than an absolute value of a maximum reverse voltage applied in a direction opposite to the polarization direction.

Preferably, the electro-mechanical transducer is a piezoelectric element.

In the invention, it is possible to provide an apparatus for driving a stacked electro-mechanical transducer in which a plurality of electro-mechanical transducers are stacked such that their polarization directions are equal to one another. In this case, the AC voltage sources are respectively connected to the electro-mechanical transducers, and the respective AC voltage sources apply AC driving voltages having different phases to the respective electro-mechanical transducers. As a result, it is possible to provide an apparatus for driving a bimorph electro-mechanical transducer.

Alternatively, the invention may provide an apparatus for driving a stacked electromechanical transducer in which a plurality of electro-mechanical transducers are stacked such that their polarization directions are opposite to one another.

In this case, by connecting each AC voltage source to each electromechanical transducer and applying AC driving voltages having opposite polarities to the electromechanical transducers, the absolute value of the maximum forward voltage applied in the polarization direction of the electro-mechanical transducer can be made to be larger than the absolute value of the maximum reverse voltage applied in the direction opposite to the polarization direction.

Further, the invention may provide an apparatus for driving a bimorph electromechanical transducer by applying AC driving voltages having different phases to the respective electromechanical transducers.

Alternatively, by applying AC driving voltages having the same phases to the respective electro-mechanical transducers, it is possible to provide an apparatus for driving a stacked electromechanical transducer in which the electromechanical transducers expand simultaneously and contract simultaneously.

In addition, when providing the stacked electro-mechanical transducer, it is possible to increase the stacked number of electro-mechanical transducers by adding other electro-mechanical transducers to the stacked electromechanical transducer composed of two electromechanical transducers. At this time, it is preferable that an AC driving voltage be applied to each of the other electro-mechanical transducers, the AC driving voltage being set such that the absolute value of the maximum forward voltage applied in the polarization direction is larger than the absolute value of the maximum reverse voltage applied in the direction opposite to the polarization direction.

Preferably, each of the other electro-mechanical transducers is opposite in the polarization direction to adjacent electromechanical transducers.

In the invention, it is preferable that the absolute value of the maximum forward voltage be larger than the product of a coercive field strength, by which the polarization disappears in an electromechanical transducer, and the film thickness of the electro-mechanical transducer.

Further, it is preferable that the absolute value of the maximum reverse voltage be smaller than the product of a coercive field strength, by which the polarization disappears in an electro-mechanical transducer, and the film thickness of the electromechanical transducer.

The invention can use a piezoelectric element having a low Curie temperature, such as barium titanate or any material which contains barium titanate as a main component but does not contain lead (Pb). Materials that do not contain lead cause a little damage to the environment.

### BRIEF DESCRIPTION OF THE DRAWINGS

FIG. 1 is a diagram showing an embodiment of the invention;

FIG. 2 is a diagram showing a piezoelectric element, which is an example of an electro-mechanical transducer, according to an embodiment of the invention;

FIG. 3 is a diagram showing a piezoelectric element, which is an example of an electro-mechanical transducer, according to another embodiment of the invention;

FIG. 4 is a diagram showing a piezoelectric element, which is an example of an electro-mechanical transducer, according to still another embodiment of the invention;

FIG. 5 is a graph showing a waveform of an AC driving voltage supplied from an AC voltage source A1;

FIG. 6 is a graph showing a waveform of an AC driving voltage supplied from an AC voltage source B1;

FIG. 7 is a graph showing a waveform of an AC driving voltage supplied from an AC voltage source C1;

FIG. 8 is a graph showing a waveform of an AC driving voltage supplied from an AC voltage source D1;

FIG. 9 is a diagram showing a conventional electro-mechanical transducer (a piezoelectric element);

FIG. 10 is a diagram showing a conventional electro-mechanical transducer (a piezoelectric element);

FIG. 11 is a diagram showing a conventional electro-mechanical transducer (a piezoelectric element);

FIG. 12 is a diagram showing a conventional electro-mechanical transducer (a piezoelectric element); and

FIG. 13 is a graph showing a waveform of an AC driving voltage supplied from an AC voltage source A.

### DESCRIPTION OF THE PREFERRED EMBODIMENTS

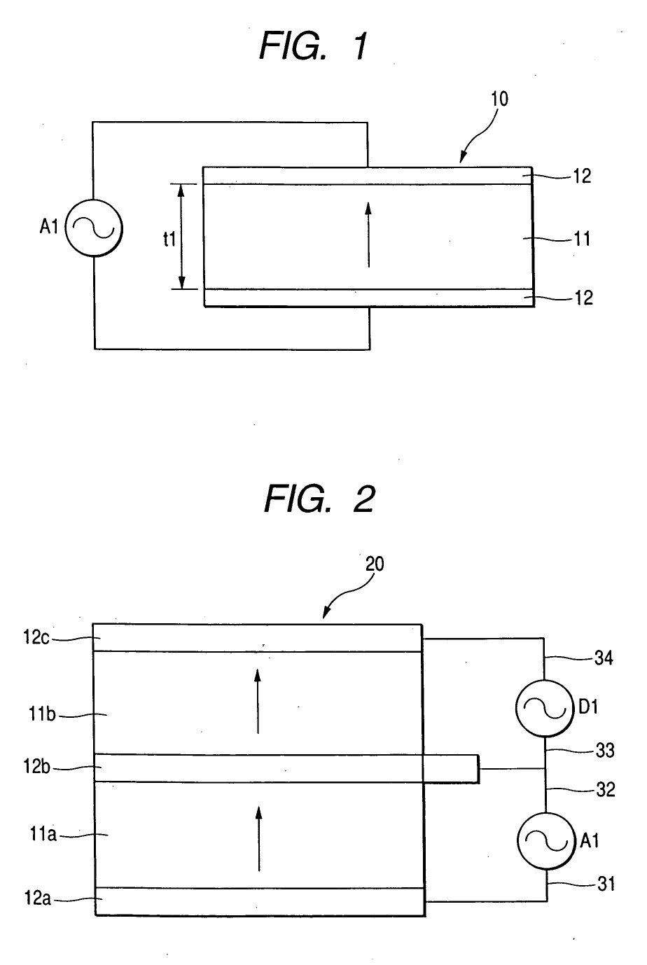

FIG. 1 is a diagram showing an embodiment of the invention.

As shown in FIG. 1, a piezoelectric element (electro-mechanical transducer) 10 includes a piezoelectric ceramic 11 and electrodes 12 each being provided on the upper and lower surfaces of the piezoelectric ceramic 11. The piezoelectric ceramic 11 is subjected to a polarization process in a thickness direction thereof. Accordingly, the electrodes 12 are disposed on both surfaces in a direction intersecting the polarization direction of the piezoelectric ceramic 11. The electrodes 12 are connected to an alternating current (AC) voltage source A1. When the rising direction of a voltage matches the polarization direction of the piezoelectric ceramic 11, the piezoelectric element 10 expands the film thickness in the voltage direction. On the contrary, when the rising direction of the voltage is opposite to the polarization direction of the piezoelectric ceramic 11, the piezoelectric element 10 contracts in the voltage direction. As will be described below, in the invention, a stacked piezoelectric element or a piezoelectric bimorph element is formed by various combinations of the piezoelectric element 10 and the AC voltage source shown in FIG. 1.

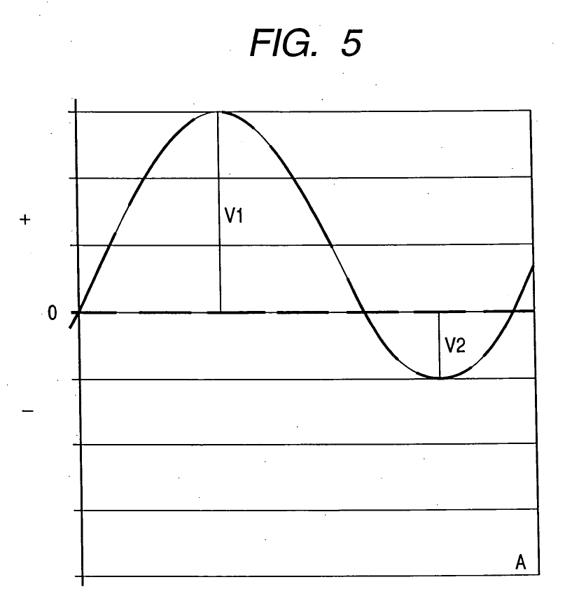

An AC driving voltage supplied from the AC voltage source A1 has a sine wave shape as shown in FIG. 5. An absolute value V1 of a maximum forward voltage which is biased in a positive voltage direction and is applied in the polarization direction (direction depicted by an arrow) of the piezoelectric ceramic 11 is set to be larger than an absolute value V2 of a maximum reverse voltage applied in an opposite direction to the polarization direction.

The polarized piezoelectric ceramic has such a property that the polarization disappears when an electric field (product of a voltage and a film thickness) having a value greater than the predetermined value is applied in a direction opposite to the polarization direction. A maximum reverse electric field by which the polarization disappears is called a coercive field strength. Accordingly, it is necessary to make a maximum reverse voltage in the direction opposite to the polarization direction smaller than a predetermined value based on the coercive field strength.

In the invention, the absolute value V1 of a maximum forward voltage applied in the polarization direction (direction depicted by an arrow) is set to be larger than the absolute value V2 of a maximum reverse voltage applied in a direction opposite to the polarization direction. Thus, it is possible to increase the displacement amount of the film thickness (t1) while preventing polarization loss of the piezoelectric ceramic 11. Also, since a pseudo polarization process of the piezoelectric ceramic can be performed by the maximum forward voltage V1 having a large absolute value while it is driven, it is possible to prevent polarization from decreasing.

According to the invention, it is possible to make the absolute value V1 of the maximum forward voltage larger than the product of the film thickness t1 and the coercive field strength (e.g., 640 kV·m) by which the polarization disappears in the piezoelectric ceramic 11.

Also, the absolute value V2 of the maximum reverse voltage is preferably smaller than the product of the film thickness t1 and the coercive field strength by which the polarization disappears in the piezoelectric ceramic 11. In particular, it is more preferable that the absolute value V2 of the maximum reverse voltage be smaller than 70% of the product of the film thickness t1 and the coercive field strength by which the polarization disappears in the piezoelectric ceramic 11. However, in the invention, since a pseudo polarization process of the piezoelectric ceramic can be performed by the maximum forward voltage while it is driven, it is also possible to make the absolute value V2 of the maximum reverse voltage close to the product of the coercive field strength and the film thickness t1.

For example, in the invention, when the absolute value of the coercive field strength of the piezoelectric ceramic 11 is 640 kV·m, the absolute value of a maximum electric field in the polarization direction can be set to 1000 kV·m and an absolute value of a maximum electric field in the direction opposite to the polarization direction can be set to 500 kV·m. Conventionally, since the maximum electric field in the polarization direction cannot be made to be larger than the maximum electric field in the direction opposite to the polarization direction, the maximum electric field in the polarization direction and the maximum electric field in the opposite direction have an absolute value equal to or below 450 kV·m.

Also, if a pseudo polarization process can be performed while driving the piezoelectric element, a usage temperature of the piezoelectric element can increase. Accordingly, it is possible to use the piezoelectric element at temperatures close to the Curie temperature (a temperature at which the polarization disappears) of the piezoelectric element. For example, if the usage temperature is denoted by Tu(K) in Kelvin temperature scale and the Curie temperature is denoted by Tc(K), the following equation can be obtained: Tu≧0.8×Tc, or Tu≧0.9×Tc.

Thus, barium titanate which has a Curie temperature as low as about 135° C. can be used as the material forming the piezoelectric ceramic 11. Barium titanate causes little damage to the environment since it does not contain lead. In the invention, the piezoelectric ceramic 11 may be formed of Pb(Ni, Nb)O3-based PZT (lead zirconate titanate).

The electrodes 12 are formed by applying Ag electrode paste on barium titanate, any material which contains barium titanate as a main component but does not contain lead (Pb), or both surfaces of a single-layered (a thickness of 0.2 μm) or stacked PZT, and then sintering it at a predetermined temperature. Next, a voltage is applied in the depicted arrow direction to polarize the piezoelectric ceramic 11. The polarization process is performed at 1200 kV·m.

A stacked piezoelectric element or a piezoelectric bimorph element can be formed by various combinations of the piezoelectric element 10 and the AC voltage source shown in FIG. 1.

The stacked piezoelectric element 10 is configured such that the polarization directions of a plurality of stacked piezoelectric ceramics 11 are the same or opposite to one another.

The piezoelectric bimorph element 20 shown in FIG. 2 can be formed by stacking two piezoelectric elements 10 such that the polarization directions of the piezoelectric ceramics 11 are the same.

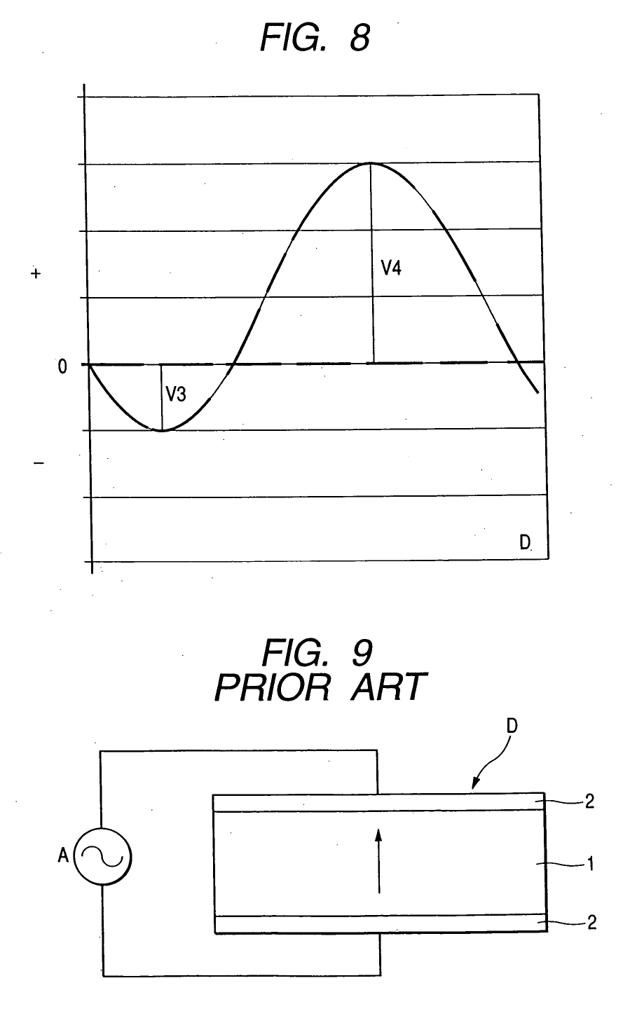

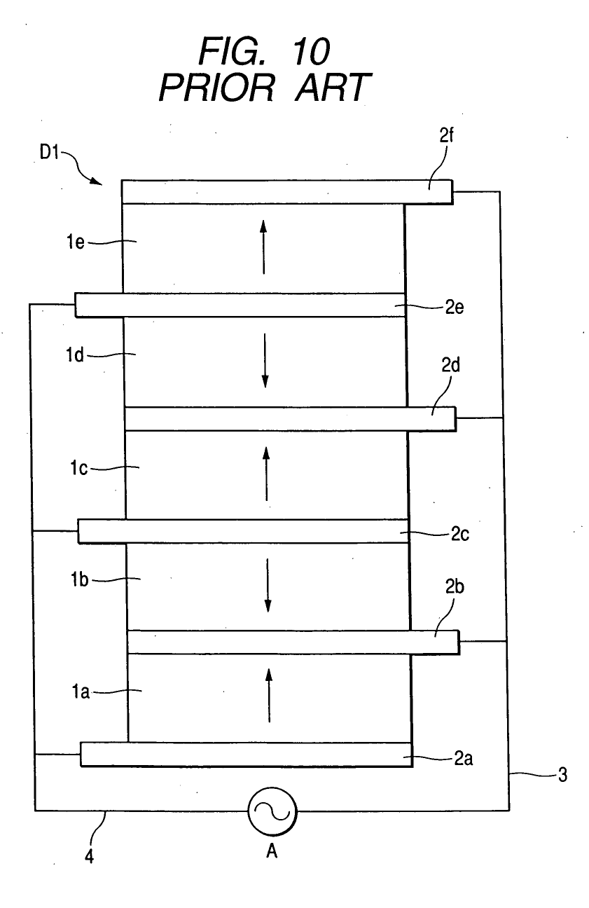

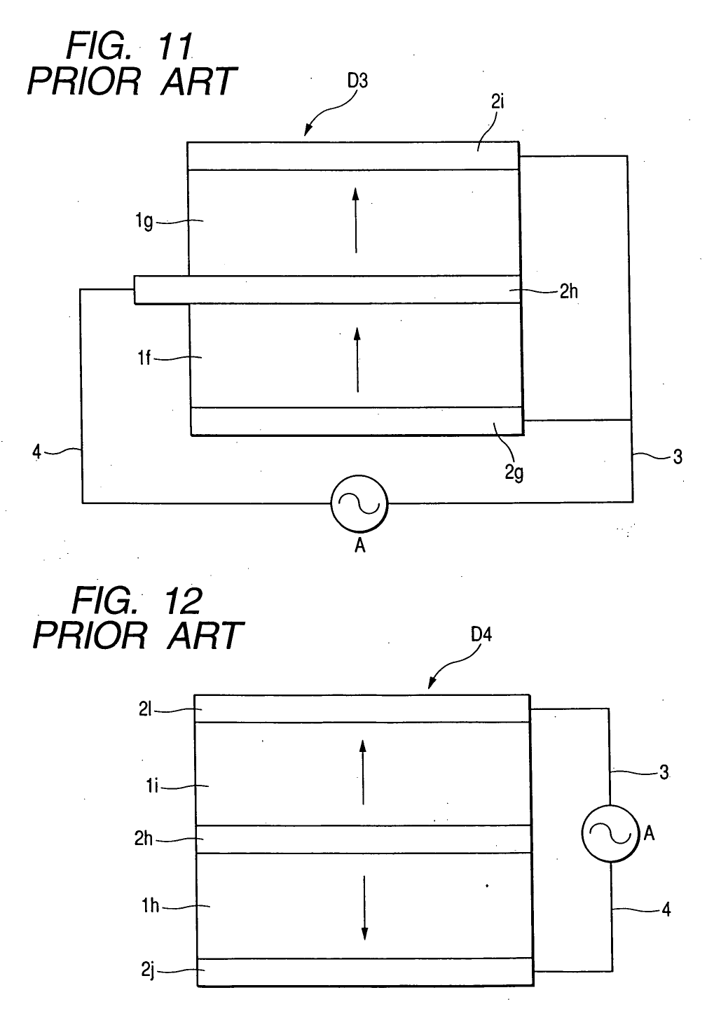

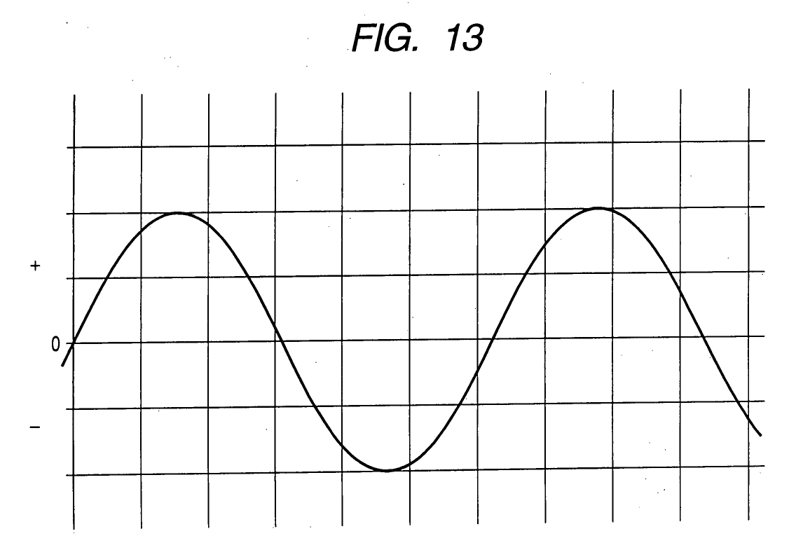

FIG. 2 is a cross-sectional view of the stacked piezoelectric element 20 formed by stacking two piezoelectric elements such as the piezoelectric element 10 shown in FIG. 1. Reference numerals 11a and 11b denote piezoelectric ceramics and reference numerals 12a, 12b, and 12c denote electrodes. The piezoelectric ceramics 11a and 11b have the same polarization directions. The electrodes 12a and 12b of the piezoelectric ceramic 11a are respectively connected to terminals 31 and 32 of the AC voltage source A1, while the electrodes 12b and 12c of the piezoelectric ceramic 11b are respectively connected to terminals 33 and 34 of an AC voltage source D1. An AC driving voltage supplied from the AC voltage source A1 has a waveform shown in FIG. 5, while an AC driving voltage supplied from the AC voltage source D1 has a waveform shown in FIG. 8.

The waveforms shown in FIGS. 5 and 8 are sine waves, the phase difference between the waveforms is 180° (2π), and both waveforms are biased to a positive voltage side. Also, the waveform of an AC driving voltage shown in FIG. 5 is a waveform indicating voltage values at the terminal 32 side with respect to the terminal 31. The waveform of an AC driving voltage shown in FIG. 8 is a waveform indicating voltage values at the terminal 34 side with respect to the terminal 33.

In FIGS. 5 and 8 in which traverse axes have equal scales, when an AC driving voltage supplied from the AC voltage source A1 is equal to a maximum positive voltage V1, an AC driving voltage supplied from the AC voltage source D1 is equal to a minimum negative voltage V3. At this time, a maximum forward voltage V1 is applied to the piezoelectric ceramic 11a so that the film thickness of the piezoelectric ceramic 11a expands in the applied voltage direction. Meanwhile, a maximum reverse voltage V3 is applied to the piezoelectric ceramic 11b so that the film thickness of the piezoelectric ceramic 11b contracts in the applied voltage direction.

Further, when an AC driving voltage supplied from the AC voltage source A1 is equal to a minimum negative voltage V2, an AC driving voltage supplied from the AC voltage source D1 is equal to a maximum positive voltage V4. At this time, a maximum reverse voltage V2 is applied to the piezoelectric ceramic 11a so that the film thickness of the piezoelectric ceramic 11a contracts in the applied voltage direction. Meanwhile, a maximum reverse voltage V4 is applied to the piezoelectric ceramic 11b so that the film thickness of the piezoelectric ceramic 11b expands in the applied voltage direction. Such an expansion and contraction of the piezoelectric ceramics 11a and 11b causes the stacked piezoelectric element D3 to curve.

Furthermore, in the invention, a positive side of a waveform of an AC driving voltage is set to a positive voltage and a negative side is set to a negative voltage. A voltage rising in a polarization direction of the piezoelectric ceramic is set to a forward voltage, and a voltage rising in an opposite direction of the polarization direction is set to a reverse voltage.

In the present embodiment, absolute values V1 and V4 of a maximum forward voltage applied in a polarization direction (a direction depicted by an arrow) are set to be larger than absolute values V2 and V3 of a maximum reverse voltage applied in an opposite direction to the polarization direction. As a result, it is possible to increase the displacement amount of the film thickness of the piezoelectric ceramics 11a and 11b while preventing the polarization loss of the piezoelectric ceramics 11a and 11b. Also, since a pseudo polarization process of the piezoelectric ceramic can be performed by the maximum forward voltage having a large absolute value while it is driven, it is possible to prevent polarization from decreasing.

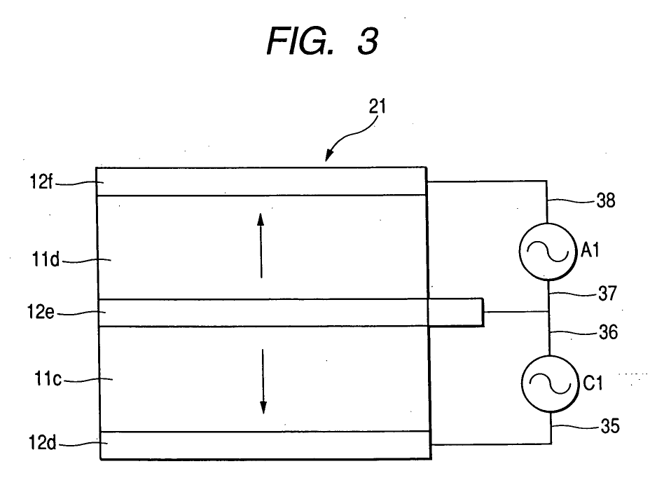

Alternatively, the piezoelectric bimorph element 21 shown in FIG. 3 can be formed by stacking two piezoelectric elements 10 so that the polarization directions of the piezoelectric ceramics 11 are opposite to each other.

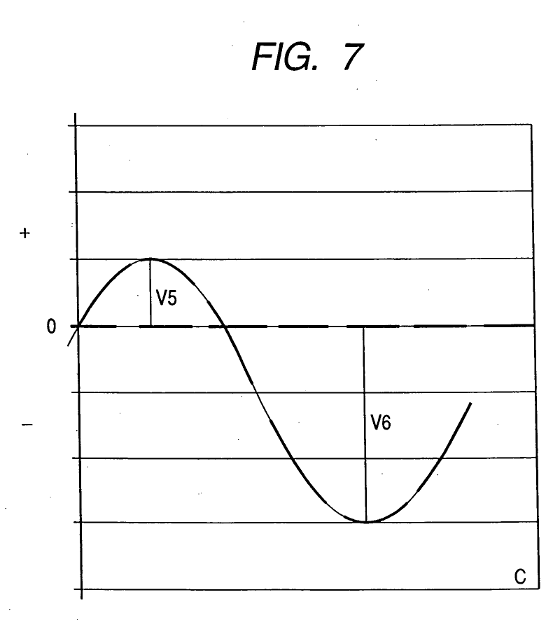

FIG. 3 is a cross-sectional view of a stacked piezoelectric element 21 in which two piezoelectric elements such as the piezoelectric element 10 shown in FIG. 1 are stacked. Reference numerals 11c and 11d denote piezoelectric ceramics, and reference numerals 12d, 12e, and 12f denote electrodes. The polarization direction of the piezoelectric ceramic 11c is opposite to the polarization direction of the piezoelectric ceramic 11d. The electrodes 12d and 12e of the piezoelectric ceramic 11c are respectively connected to the terminals 35 and 36 of an AC voltage source C1, while the electrodes 12e and 12f of the piezoelectric ceramic 11d are respectively connected to the terminals 37 and 38 of an AC voltage source A1. The AC driving voltage supplied from the AC voltage source C1 has a waveform shown in FIG. 7, while the AC driving voltage supplied from the AC voltage source A1 has a waveform shown in FIG. 5.

Waveforms shown in FIGS. 5 and 7 are sine waves which have the same phase as each other. The AC driving voltage of the waveform shown in FIG. 5 is biased at a positive voltage side, while the AC driving voltage of a waveform shown in FIG. 7 is biased at a negative voltage side. Also, the waveform of the AC driving voltage shown in FIG. 7 is a waveform indicating voltage values at the terminal 36 side relative to the terminal 35, while the waveform of the AC driving voltage shown in FIG. 5 is a waveform indicating voltage values at the terminal 38 side relative to the terminal 37.

In FIGS. 5 and 7 in which traverse axes have equal scales, when an AC driving voltage supplied from the AC voltage source A1 is equal to a maximum positive voltage V1, an AC driving voltage supplied from the AC voltage source C1 is also equal to a maximum positive voltage V5. At this time, a maximum forward voltage V1 is applied to the piezoelectric ceramic 11d so that the film thickness of the piezoelectric ceramic 11d expands in the applied voltage direction. Meanwhile, a maximum reverse voltage V5 is applied to the piezoelectric ceramic 11c so that the film thickness of the piezoelectric ceramic 11c contracts in the applied voltage direction.

Also, when an AC driving voltage supplied from the AC voltage source A1 is equal to a minimum negative voltage V2, an AC driving voltage supplied from the AC voltage source C1 is equal to a minimum negative voltage V6. At this time, a maximum reverse voltage V2 is applied to the piezoelectric ceramic 11d so that the film thickness of the piezoelectric ceramic 11d contracts in the applied voltage direction, while a maximum forward voltage V6 is applied to the piezoelectric ceramic 11c so that the film thickness of the piezoelectric ceramic 11c expands in the applied voltage direction. Such an expansion and contraction of the piezoelectric ceramics 11c and 11d causes the stacked piezoelectric element D3 to curve.

In the invention, a positive side of a waveform of an AC driving voltage is set to a positive voltage, while a negative side is set to a negative voltage. A voltage rising in a polarization direction of the piezoelectric ceramic is set to a forward voltage, while a voltage rising in an opposite direction of the polarization direction is set to a reverse voltage.

Thus, as described above, when the AC driving voltage supplied from the AC voltage source C1 is equal to the minimum negative voltage V6, the maximum forward voltage V6 is applied across the piezoelectric ceramic 11c, since voltage values at the terminal 35 of the AC voltage source C1 with respect to the terminal 36 are positive when voltage values at the terminal 36 with respect to the terminal 35 are negative.

Also in the piezoelectric element of the present embodiment, absolute values V1 and V6 of a maximum forward voltage applied in the polarization direction (a direction depicted by an arrow) are set to be larger than absolute values V2 and V5 of a maximum reverse voltage applied in an opposite direction to the polarization direction. Thus, it is possible to increase the displacement amount of the film thickness of the piezoelectric ceramic 11c and 11d while preventing polarization loss of the piezoelectric ceramic 11c and 11d. Also, since a pseudo polarization process of the piezoelectric ceramic can be performed by the maximum forward voltage having a large absolute value while it is driven, it is possible to prevent polarization from decreasing.

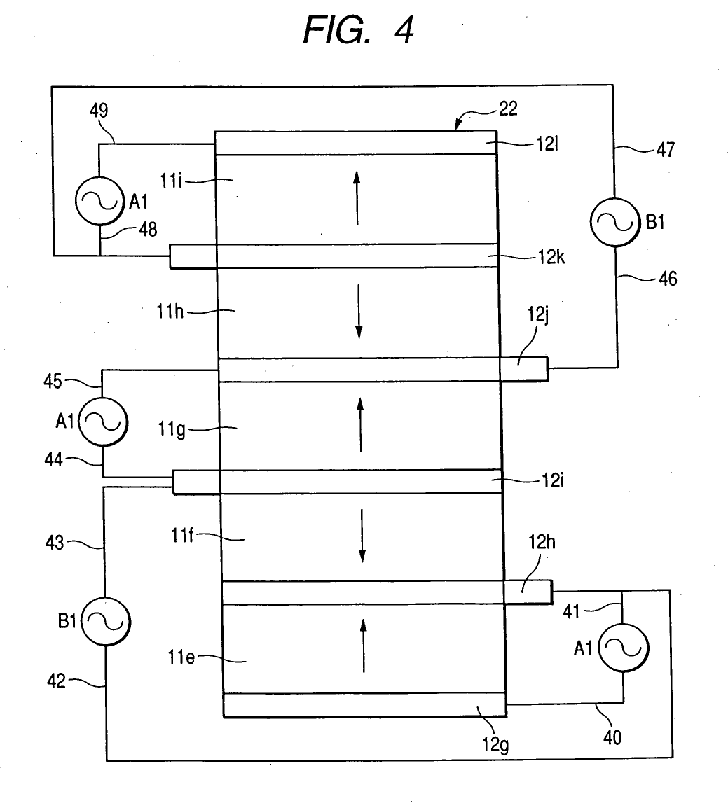

FIG. 4 is a cross-sectional view of a stacked piezoelectric element 22 in which a plurality of piezoelectric elements such as the piezoelectric element 10 shown in FIG. 1 are stacked. Reference numerals 11e, 11f, 11g, 11h, and 11i denote piezoelectric ceramics, and reference numerals 12g, 12h, 12i, 12j, 12k, and 12l denote electrodes. The polarization directions of the piezoelectric ceramics 11e, 11g, and 11i are opposite to the polarization directions of the piezoelectric ceramics 11f and 11h.

The piezoelectric element 22 is configured such that piezoelectric ceramics are stacked on the piezoelectric ceramic 11g (another electro-mechanical transducer) so that the polarization directions of the piezoelectric ceramics are opposite to each other.

The electrodes 12g and 12h of the piezoelectric ceramic 11e are respectively connected to the terminals 40 and 41 of the AC voltage source A1, while the electrodes 12h and 12i of the piezoelectric ceramic 11f are respectively connected to the terminals 42 and 43 of the AC voltage source B1. Also, the electrodes 12j and 12k of the piezoelectric ceramic 11h are respectively connected to the terminals 46 and 47 of the AC voltage source B1, while the electrodes 12k and 12l of the piezoelectric ceramic 11i are respectively connected to the terminals 48 and 49 of the AC voltage source A1. Also, the electrodes 12i and 12j of the piezoelectric ceramic 11g (another electromechanical transducer) are respectively connected to the terminals 44 and 45 of the AC voltage source A1.

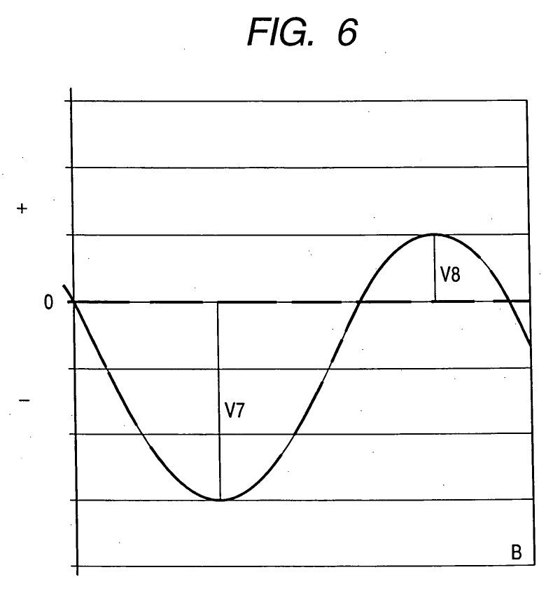

An AC driving voltage supplied from the AC voltage source A1 has a waveform shown in FIG. 5, while an AC driving voltage supplied from the AC voltage source B1 has a waveform shown in FIG. 6.

The waveforms shown in FIGS. 5 and 6 are sine waves which have the same phase as each other, but with opposite voltage polarities. The AC driving voltage of the waveform shown in FIG. 5 is biased at a positive voltage side, while the AC driving voltage of the waveform shown in FIG. 6 is biased at a negative voltage side. Also, the waveform of the AC driving voltage shown in FIG. 5 is a waveform indicating voltage values at the terminals 41, 45, or 49 with respect to the terminals 40, 44, or 48. The waveform of the AC driving voltage shown in FIG. 6 is a waveform indicating voltage values at the terminal 43 or 47 with respect to the terminal 42 or 46.

In FIGS. 5 and 7 in which traverse axes have equal scales, when an AC driving voltage supplied from the AC voltage source A1 is equal to a maximum positive voltage V1, an AC driving voltage supplied from the AC voltage source B1 is equal to a minimum negative voltage V7. At this time, a maximum forward voltage V1 is applied to the piezoelectric ceramics 11e, 11g, and 11i so that the film thicknesses of the piezoelectric ceramics 11e, 11g, and 11i expand in the applied voltage direction.

At the same time, the AC voltage source B1 has a negative value at the terminal 43 or 47 with respect to the terminal 42 or 46. That is, the voltage value at the terminal 42 or 46 with respect to the terminal 43 or 47 is positive. Thus, a maximum forward voltage V7 is applied to the piezoelectric ceramics 11f and 11h so that the film thicknesses of the piezoelectric ceramic 11f and 11h also expand in the applied voltage direction.

Further, when the AC driving voltage supplied from the AC voltage source A1 is equal to a minimum negative voltage V2, the AC driving voltage supplied from the AC voltage source B1 is equal to a maximum positive voltage V8. At this time, a maximum reverse voltage V2 is applied to the piezoelectric ceramic 11e, 11g, and 11i so that the film thicknesses of the piezoelectric ceramics 11e, 11g, and 11i contract in the applied voltage direction, while the maximum reverse voltage V8 is also applied to the piezoelectric ceramic 11f and 11h so that the film thicknesses of the piezoelectric ceramics 11f and 11h contract in the voltage direction.

That is, in the piezoelectric element 22, all of the piezoelectric ceramics 11e, 11f, 11g, 11h, and 11i expand simultaneously and contract simultaneously.

In addition, in the invention, a positive side of the waveform of the AC driving voltage is set to a positive voltage and a negative side thereof is set to a negative voltage. A voltage rising in a polarization direction of the piezoelectric ceramic is set to a forward voltage, and a voltage rising in an opposite direction of the polarization direction is set to a reverse voltage.

Also in the present embodiment, absolute values V1 and V7 of a maximum forward voltage applied in a polarization direction (a direction depicted by an arrow) are set to be larger than absolute values V2 and V8 of a maximum reverse voltage applied in a direction opposite to the polarization direction. As a result, it is possible to increase the displacement amount of the film thickness of the piezoelectric ceramics 11a and 11b while preventing the polarization loss of the piezoelectric ceramics 11e, 11f, 11g, 11h, and 11i. Also, since a pseudo polarization process of the piezoelectric ceramic can be performed by the maximum forward voltage having a large absolute value while it is driven, it is possible to prevent polarization from decreasing.

A material of the piezoelectric ceramics 11a, 11b, 11c, 11d, 11e, 11f, 11g, 11h, and 11i in the piezoelectric elements 20, 21, and 22 shown in FIGS. 2 to 4 are the same as that of the piezoelectric ceramic 11 shown in FIG. 1. Also, materials of the electrodes 12a, 12b, 12c, 12d, 12e, 12f, 12g, 12h, 12i, 12j, 12k, and 12l are also formed of the Ag electrode paste like that of the electrode 12.

Moreover, a plurality of piezoelectric ceramics with electrodes interposed therebetween can be stacked by attaching a plurality of stacked piezoelectric ceramics with the electrodes applied thereon, or by sintering a plurality of stacked piezoelectric ceramics with Ag electrode pastes interposed therebetween.

Also in the piezoelectric elements 20, 21, and 22 shown in FIGS. 2 to 4, it is possible to make an absolute value of the maximum forward voltage larger than the product of the film thickness of the piezoelectric ceramic and the coercive field strength (e.g., 640 kV·m). Also, an absolute value of the maximum reverse voltage is preferably smaller than the product of the film thickness of the piezoelectric ceramic and the coercive field strength. In particular, it is more preferable that the absolute value of the maximum reverse voltage be smaller than 70% of the product of the film thickness of the piezoelectric ceramic and the coercive field strength. However, in the invention, since a pseudo polarization process of the piezoelectric ceramic can be performed by the maximum forward voltage while it is driven, it is also possible to make the absolute value of the maximum reverse voltage equal to the product of the coercive field strength and the film thickness or larger than 70% of the product of the coercive field strength and the film thickness.

In the invention, for example, when the absolute value of the coercive field strength of the piezoelectric ceramic is 640 kV·m, an absolute value of a maximum electric field in the polarization direction can be set to be 1000 kV·m and an absolute value of a maximum electric field in a direction opposite to the polarization direction can be set to be 500 kV·m.

Further, if a pseudo polarization process can be performed while the piezoelectric element is driven, a usage temperature of the piezoelectric element can increase. Accordingly, it is possible to use barium titanate having a Curie temperature as low as about 135° C. as a material of the piezoelectric ceramic. Barium titanate causes little damage to the environment since it does not contain lead. In the invention, the piezoelectric ceramic may be formed of Pb(Ni, Nb)O3-based PZT.

Furthermore, since the AC voltage source is connected to the individual piezoelectric ceramics and an optimum AC driving voltage is applied to the individual piezoelectric ceramic, it is possible to maximize the displacement amount of the film thickness of the piezoelectric ceramic while preventing the polarization loss of the piezoelectric ceramic.

As apparent from the above description, according to the invention, it is possible to increase the displacement amount of the film thickness of an electro-mechanical transducer while preventing the polarization loss of the electromechanical transducer. Further, since a pseudo polarization process of the electro-mechanical transducer can be performed by a maximum forward voltage having a large absolute value while it is driven, it is possible to increase a usage temperature of the electro-mechanical transducer.

1. A method of driving an electro-mechanical transducer, the electro-mechanical transducer being subjected to a polarization process in one direction, being provided with electrodes on both surfaces thereof intersecting the polarization direction, and changing the film thickness thereof by applying a voltage across both electrodes,
wherein an absolute value of a maximum forward voltage applied to the electro-mechanical transducer in the polarization direction is set to be larger than an absolute value of a maximum reverse voltage applied in a direction opposite to the polarization direction.

2. The method according to claim 1,
wherein the electro-mechanical transducer is a piezoelectric element.

3. The method of driving an electro-mechanical transducer according to claim 1,
wherein a plurality of electro-mechanical transducers are stacked to be equal to one another in the polarization directions thereof.

4. The method of driving an electromechanical transducer according to claim 3,
wherein AC driving voltages having different phases are applied to the electromechanical transducers, respectively.

5. The method of driving an electro-mechanical transducer according to claim 1,
wherein adjacent electromechanical transducers are stacked to be opposite to each other in the polarization directions thereof.

6. The method of driving an electro-mechanical transducer according to claim 5,
wherein AC driving voltages having opposite polarities are applied to the electro-mechanical transducers, respectively.

7. The method of driving an electromechanical transducer according to claim 6,
wherein AC driving voltages having different phases are applied to the electromechanical transducers, respectively.

8. The method of driving an electro-mechanical transducer according to claim 1,
wherein the electromechanical transducers are stacked with other electro-mechanical transducers therebetween, and
an AC driving voltage is applied to each of the other electro-mechanical transducers, the AC driving voltage being set such that the absolute value of the maximum forward voltage applied in the polarization direction is larger than the absolute value of the maximum reverse voltage applied in the direction opposite to the polarization direction.

9. The method of driving an electro-mechanical transducer according to claim 8,
wherein each of the other electro-mechanical transducers is opposite in the polarization direction to adjacent electro-mechanical transducers.

10. The method of driving an electromechanical transducer according to claim 1,
wherein the absolute value of the maximum forward voltage is larger than the product of the film thickness of the electro-mechanical transducer and a coercive field strength by which the polarization disappears in the electromechanical transducer.

11. The method of driving an electro-mechanical transducer according to claim 1,
wherein the absolute value of the maximum reverse voltage is smaller than the product of the film thickness of the electromechanical transducer and a coercive field strength by which the polarization disappears in the electromechanical transducer.

12. The method of driving an electro-mechanical transducer according to claim 1,
wherein the piezoelectric element is made of a material which contains barium titanate as a main component but does not contain lead.

13. An apparatus for driving an electromechanical transducer, comprising:
an electromechanical transducer that is subjected to a polarization process in one direction, is provided with electrodes on both surfaces thereof intersecting the polarization direction, and changes the film thickness thereof by applying a voltage across both electrodes; and
an AC voltage source that applies an AC driving voltage to the electro-mechanical transducer,
wherein an absolute value of a maximum forward voltage of the AC driving voltage applied to the electro-mechanical transducer in the polarization direction is larger than an absolute value of a maximum reverse voltage applied in a direction opposite to the polarization direction.

14. The apparatus for driving an electro-mechanical transducer according to claim 13,
wherein the electro-mechanical transducer is a piezoelectric element.

15. The apparatus for driving an electro-mechanical transducer according to claim 13,
wherein a plurality of electromechanical transducers are stacked to be equal to one another in the polarization direction thereof.

16. The apparatus for driving an electro-mechanical transducer according to claim 15,
wherein the respective AC voltage sources are connected to the respective electromechanical transducers, and the respective AC voltage sources apply AC driving voltages having different phases to the respective electro-mechanical transducers.

17. The apparatus for driving an electro-mechanical transducer according to claim 13,
wherein the electro-mechanical transducers are stacked to be opposite to one another in the polarization directions thereof.

18. The apparatus for driving an electromechanical transducer according to claim 17,
wherein the respective AC voltage sources are connected to the respective electro-mechanical transducers, and AC driving voltages having opposite polarities are applied to the respective electro-mechanical transducers.

19. The apparatus for driving an electro-mechanical transducer according to claim 18,
wherein the respective AC voltage sources apply AC driving voltages having different phases to the respective electro-mechanical transducers.

20. The apparatus for driving an electro-mechanical transducer according to claim 15,
wherein the electro-mechanical transducers are stacked with other electro-mechanical transducers therebetween, and
an AC voltage source is connected to apply an AC driving voltage to each of the other electro-mechanical transducers, the AC driving voltage being set such that the absolute value of the maximum forward voltage applied in the polarization direction is larger than the absolute value of the maximum reverse voltage applied in the direction opposite to the polarization direction.

21. The apparatus for driving an electro-mechanical transducer according to claim 20,
wherein each of the other electromechanical transducers is opposite in the polarization direction thereof to adjacent electro-mechanical transducers.

22. The apparatus for driving an electromechanical transducer according to claim 13,
wherein the absolute value of the maximum forward voltage is larger than the product of the film thickness of the electromechanical transducer and a coercive field strength by which the polarization disappears in the electro-mechanical transducer.

23. The apparatus for driving an electromechanical transducer according to claim 13,
wherein the absolute value of the maximum reverse voltage is smaller than the product of the film thickness of the electromechanical transducer and a coercive field strength by which the polarization disappears in the electro-mechanical transducer.

24. The apparatus for driving an electromechanical transducer according to claim 13,
wherein the piezoelectric element is made of a material which contains barium titanate as a main component but does not contain lead.
